(19) United States
(12) Patent Application Publication
(10) Pub. No.: US 2008/0102630 A1
(43) Pub. Date: May 1, 2008

(54) Method of manufacturing semiconductor device

(75) Inventor: Masayoshi Saito, Tokyo (JP)

Correspondence Address: Paul J. Esatto, Jr.;Scully, Scott, Murphy & Presser, P.C., Suite 300, 400 Garden City Plaza, Garden City, NY, 11530, US

(73) Assignee: Elpida Memory, Inc., Tokyo (JP)

(21) Appl. No.: 11/973,947

(22) Filed: Oct. 11, 2007

(30) Foreign Application Priority Data
Oct. 25, 2006 (JP) 2006-289442

(51) Int. Cl. H01L 21/44

(52) U.S. Cl. 438/685; 438/687; 257/E21.476

(57) ABSTRACT

In a method of manufacturing a semiconductor device, an insulating film with a concave portion is formed on a semiconductor wafer. A barrier layer is formed on the insulating film to cover a surface of the insulating film such that the barrier layer has a uniform crystal orientation over a whole wafer surface of the semiconductor wafer. A metal film is formed on the barrier layer such that a portion of the metal film fills the concave portion, and a CMP (Chemical Mechanical Polishing) method is performed on the metal film to leave the filling portion of the metal film.

### BACKGROUND OF THE INVENTION

The present invention relates to a method of manufacturing a semiconductor device, and more particularly, to a method of manufacturing multi-level interconnection.

A low-resistance metal plug is used to connect a lower wiring layer and an upper wiring layer in a semiconductor device. The metal plug such as a tungsten plug is formed as follows. First, a barrier layer including a titanium film (Ti film) and a titanium nitride film (TiN film) are formed on an interlayer insulating film in which via-holes are formed. Subsequently, a tungsten film (W film) is formed on the barrier layer by a CVD (Chemical Vapor Deposition) method. Subsequently, an extra portion of the tungsten and barrier films on the flat surface of the interlayer insulating film is removed by a CMP (Chemical Mechanical Polishing) method so that the barrier layer and the tungsten film filling the via-hole are left.

In the above method of forming the tungsten plug, it is important to detect an end point of a process of removing the barrier layer and the tungsten film by the CMP method in a high precision. If a timing at which the process is ended is too late, a connection resistance of the tungsten plug will increase because of excessive polishing. An increase of a wiring capacitance may also be occurred. If the timing at which the process is ended is too early, adjacent tungsten plugs will make a short circuit because of insufficient polishing.

Japanese Laid Open Patent application (JP-P2002-203858A) discloses a technique of forming a tungsten film as a polycrystalline film whose crystal plane is (110)-oriented, in order to detect the end point of the process of removing the tungsten film by the CMP method with high precision. Moreover, the above Japanese Laid Open Patent application (JP-P2002-203858A) describes that, when a diffraction angle is measured by a 2• method using an X-ray diffractometer, the titanium nitride film is oriented such that its crystal plane is (220) oriented with a half-value width of 2 degrees or less, and a crystalline orientation of the tungsten film is surely improved.

By the way, Japanese Laid Open Patent Application (JP-A-Heisei 8-162530) discloses a fact that, if the titanium film has a (002) orientation plane and a titanium nitride film thereon has a (111) orientation plane, an anneal temperature when the titanium film is nitrided through annealing can be set lower. This is because the (002) orientation plane of titanium is relatively active and is easy to be nitrided, and nitrogen is easy to diffuse in a normal direction to a (111) orientation plane of titanium nitride.

Japanese Laid Open Patent Application (JP-P2003-142577A) discloses a technique that forms a W film by the CVD method after the ALD (atomic layer deposition) TiN film is formed on the sputtered TiN(111)/Ti films, in order to reduce the p/n junction leakage current.

The above documents in the related art did not indicate the distribution of the character of the films in the wafers at all, and there is a case that some metal films remain in the peripheral region of a wafer after CMP even if the end-point control of CMP is appropriate in the center region of the wafer. Therefore, it is necessary to form a uniform metal film all over the wafer with a large diameter, and to precisely control the amount of CMP all over a whole wafer.

### SUMMARY

An object of the present invention is to provide a method of manufacturing a semiconductor device in which a metal film can be polished by a CMP method over a whole wafer.

In an aspect of the present invention, a method of manufacturing a semiconductor device is achieved by forming an insulating film with a concave portion on a semiconductor wafer; by forming a barrier layer on the insulating film to cover a surface of the insulating film such that the barrier layer has a uniform crystal orientation over a whole wafer surface of the semiconductor wafer; by forming a metal film on the barrier layer such that a portion of the metal film fills the concave portion; and by performing a CMP (Chemical Mechanical Polishing) method on the metal film to leave the filling portion of the metal film.

Here, the forming the barrier layer may be achieved by forming a metal nitride film as a nitride film of refractory metal. In this case, the metal nitride film may be formed by a reactive sputtering method. Also, a film of the refractory metal is formed and then the metal nitride film may be formed on the refractory metal film.

The refractory metal is desirably selected from the group consisting of titanium (Ti), tantalum (Ta), and molybdenum (Mo). The metal is tungsten (W).

The forming a barrier film may be achieved by providing the semiconductor wafer and a refractory metal target in a reaction chamber to oppose to each other; and by supplying a mixed gas containing an inert gas and a nitrogen gas between the semiconductor wafer and the target to flow from a peripheral portion of the semiconductor wafer to a central portion thereof. In this case, it is desirable that a nitrogen gas flow rate ratio as a ratio of a flow rate of the nitrogen gas to the mixed gas flow rate falls within a predetermined range in which a hysteresis is not observed in a change of a film forming rate of the metal nitride film when the nitrogen gas flow rate ratio is changed.

Also, the supplying a mixed gas may be achieved by introducing the mixed gas while increasing a ratio of a flow rate of the nitrogen gas to a flow rage of the mixed gas.

Also, the titanium nitride film may be formed by a sputtering method using self-ionization plasma. In this case, the forming the titanium nitride film by a sputtering method using self ionization plasma may be achieved by arranging the semiconductor wafer and a titanium target in a reaction chamber; by controlling a temperature of the semiconductor wafer to be higher than a room temperature and lower than 50° C.; by introducing the mixed gas containing an inert gas and a nitrogen gas into the reaction chamber; by controlling a frequency of a high frequency electric power to be higher than 40 MHz and lower than 200 MHz; and by controlling a pressure of the reaction chamber to be higher than 0.5 mTorr and lower than 2 mTorr.

Also, the concave portion may be a via-hole in a multi-layer interconnection, or a trench for a multi-layer interconnection. The metal film may be a copper film.

According to the present invention, the method of manufacturing a semiconductor device that allows polishing of a metal film by the CMP method to be performed neither more nor less over the whole wafer can be provided.

### BRIEF DESCRIPTION OF THE DRAWINGS

FIG. 1 is a flowchart showing a method of manufacturing a semiconductor device according to a first embodiment of the present invention;

FIGS. 2A to 2F are sectional views of a semiconductor wafer to show a process of forming a multi-level interconnection including a tungsten plug in the method of manufacturing the semiconductor device according to the first embodiment of the present invention;

FIG. 3 is a schematic diagram of a reactive sputtering apparatus used for the method of manufacturing a semiconductor device according to the first embodiment of the present invention;

FIG. 4 is a diagram showing film-forming conditions when a titanium nitride film is formed by a reactive sputtering method in the method of manufacturing the semiconductor device according to the first embodiment of the present invention;

FIGS. 5A and 5B are graphs showing X-ray diffraction spectra in a central portion and peripheral portion of a titanium nitride film formed under second conditions of FIG. 4, respectively;

FIGS. 6A and 6B are graphs showing X-ray diffraction spectra in the central portion and the peripheral portion of a tungsten film formed on the titanium nitride film, respectively;

FIG. 7 is a top view of the semiconductor wafer in case of forming the titanium nitride film under the second conditions of FIG. 4, forming the tungsten film on it, and performing a CMP method on the tungsten film;

FIGS. 8A and 8B are graphs showing X-ray diffraction spectra in the central portion and peripheral portion of a titanium nitride film formed under first conditions of FIG. 4, respectively;

FIGS. 9A and 9B are graphs showing X-ray diffraction spectra in the central portion and peripheral portion of a tungsten film formed on the titanium nitride film, respectively;

FIG. 10 is a top view of the semiconductor wafer in case of forming the titanium nitride film under the first conditions of FIG. 4, forming the tungsten film on it, and performing the CMP method on the tungsten film;

FIG. 11 is a graph showing a relation of sputtering rate and an N₂ gas flow rate ratio of introduced gas in case of forming the titanium nitride film by the reactive sputtering method;

FIGS. 12A and 12B are graphs showing X-ray diffraction spectra in the central portion and peripheral portion of a titanium nitride film formed by a high-ionization sputtering method, respectively;

FIG. 13 is a flowchart showing a modification of the method of manufacturing the semiconductor device according to a second embodiment of the present invention; and

FIGS. 14A to 14D are sectional views of the semiconductor wafer to show a process of forming an upper layer interconnection in the modification of the method of manufacturing the semiconductor device according to the second embodiment of the present invention.

### DESCRIPTION OF THE PREFERRED EMBODIMENTS

Hereinafter, a method of manufacturing a semiconductor device according to the present invention will be described in detail with reference to the attached drawings.

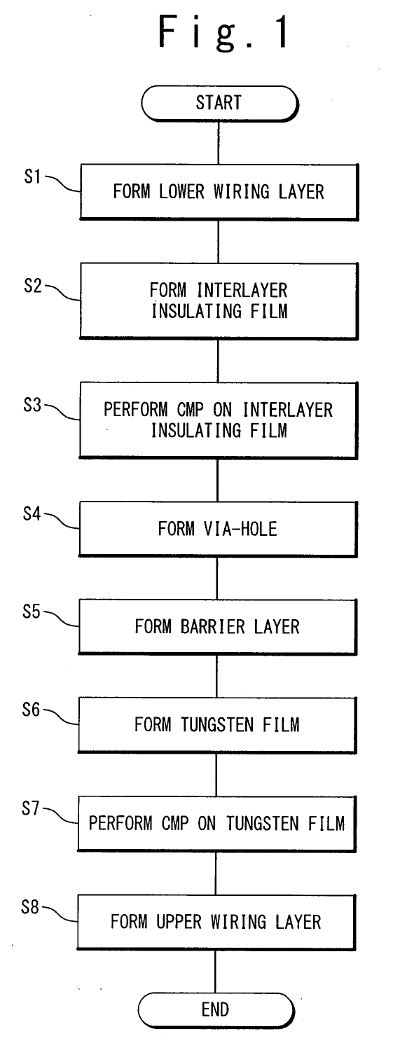

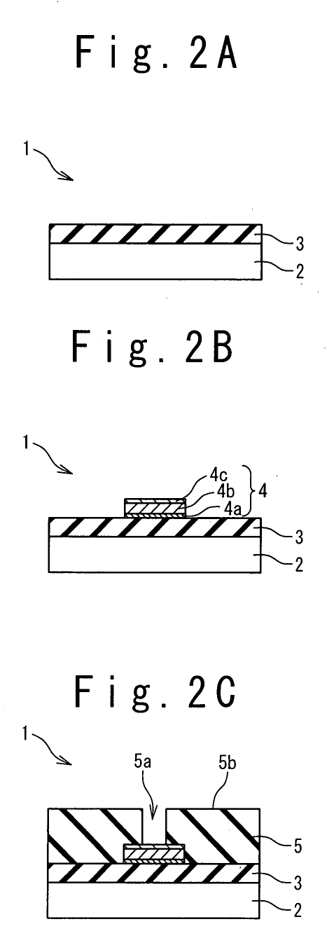

First, an outline of the method of manufacturing the semiconductor device according to a first embodiment of the present invention will be described with reference to FIG. 1 and FIGS. 2A to 2F.

FIG. 1 is a flowchart showing the method of manufacturing the semiconductor device according to the first embodiment of the present invention. FIG. 1 shows a process of forming multiple wiring layers on a semiconductor wafer 1 on which transistors have been formed. After the multiple wiring layers are formed, a passivation film is formed on the semiconductor wafer 1, which is then diced into a plurality of semiconductor chips. Each semiconductor chip is mounted on a lead frame, each terminal of the lead frame is connected with one electrode pad of the semiconductor chip, and the semiconductor chip is molded with resin. Then, a semiconductor device (semiconductor integrated circuit) is completed by passing through a test process. As the semiconductor devices, a volatile memory, a nonvolatile memory, and a logic integrated circuit are exemplified.

FIGS. 2A to 2F are sectional views of the semiconductor wafer 1 to show a process of forming multiple wiring layers including a tungsten plug 7a in the method of manufacturing the semiconductor device according to the first embodiment of the present invention.

At a step S1 as shown in FIG. 2A, a lower wiring layer 4 is formed on the semiconductor wafer 1. The semiconductor wafer 1 is prepared in the following way. That is, device isolation regions (not shown) are formed on a semiconductor substrate 2, transistors (not shown) are formed on the semiconductor wafer 1, an insulating film 3 is deposited, the insulating film 3 is flattened, and contact layers (not shown) are formed in the insulating film 3. The lower wiring layer 4 is formed on the insulating film 3. As shown in FIG. 2B, the lower wiring layer 4 has a laminate structure of a TiN/Ti film 4a in which a TiN film is formed on a Ti film, an AlCu film 4b, and a TiN film 4c. That is, in the lower wiring layer 4, the TiN/Ti film 4a is arranged on the side near the insulating film 3, the TiN film 4c is arranged on the side far from the insulating film 3, and the AlCu film 4b is arranged between the TiN/Ti film 4a and the TiN film 4c. The TiN/TI film 4a includes a titanium film (Ti film) that is formed on the side nearer the insulating film 3 and a titanium nitride film (TiN film) formed on it. For example, the thickness of the titanium film of the TiN/Ti film 4a is 20 nm, the thickness of the titanium nitride film of TiN/Ti film 4a is 30 nm, the thickness of the AlCu film 4b is 300 nm, and the thickness of the TiN film 4c is 50 nm.

Next, at a step S2 shown in FIG. 2C, an insulating layer 5 as an interlayer insulating film is formed on the semiconductor wafer 1. The insulating layer 5 is, for example, a silicon oxide film (SiO₂ film) formed by a plasma CVD (Chemical Vapor Deposition) method. Subsequently, at a step S3, the insulating layer 5 is flattened by a CMP (Chemical Mechanical Polishing) method.

Next, at a step S4 shown in FIG. 2C, a via-hole 5a is formed as a cavity (recess) of the insulating layer 5. The lower wiring layer 4 is exposed at the bottom of the via-hole 5a. A section of the insulating layer 5 on which the via-hole 5a is not formed is referred to as a flat section 5b.

Next, at a step S5 shown in FIG. 2D, a barrier layer 6 is formed on the interlayer insulating layer 5. The barrier layer 6 is a titanium nitride film (TiN film) formed by a reactive sputtering method. The titanium nitride film is formed on the flat section 5b to have the film thickness of 50 nm. The uniform barrier film is formed from the center region to the peripheral region, to cover the allover surface of the wafer. The barrier layer 6 may also include a titanium film (Ti film) as a base for the titanium nitride film. Since the barrier layer 6 is required to have a tolerance to a heat treatment in a later process, preferably it is a nitride film of a refractory metal. The refractory metals are such as titanium (Ti), tantalum (Ta), and molybdenum (Mo).

Next, at a step S6 shown in FIG. 2D, a tungsten film (W film) 7 is formed on the barrier layer 6. The tungsten film 7 is deposited by a CVD method. A part of the tungsten film 7 fills the via-hole 5a and the other part thereof is formed on the barrier layer 6. The tungsten film 7 is formed to have the thickness of 400 nm on the flat section 5b. Now, in forming the tungsten film 7 by the CVD method, a raw material gas including tungsten hexafluoride (WF₆) is used. The barrier layer 6 prevents WF₆ from reacting with the lower wiring layer 4. Moreover, if the tungsten film 7 is directly formed on the insulating layer 5, the adhesion between the insulating layer 5 and the tungsten film 7 is a problem. However, when the barrier layer 6 intervenes between these films, an excellent fitness can be obtained.

Next, at a step S7 shown in FIG. 2E, the tungsten film 7 is polished by a CMP method, so that the tungsten film 7 formed on the flat section 5b is removed. Through this polishing, a tungsten plug 7a is formed to fill the via-hole 5a.

Next, at a step S8 shown in FIG. 2F, an upper wiring layer 8 is formed on the interlayer insulating layer 5. The upper wiring layer 8 is formed to be connected with the tungsten plug 7a. The upper wiring layer 8 has a laminate structure including a TiN/Ti film 8a, an AlCu film 8b, and a TiN film 8c. In the upper wiring layer 8, the TiN/Ti film 8a is arranged on the side near the insulating layer 5, the TiN film 8c is arranged on the side far from the insulating layer 5, and the AlCu film 8b is arranged between the TiN/Ti film 8a and the TiN film 8c. The TiN/Ti film 8a includes a titanium film (Ti film) on the side closer to the insulating layer 5 and a titanium nitride film (TiN film) formed on it.

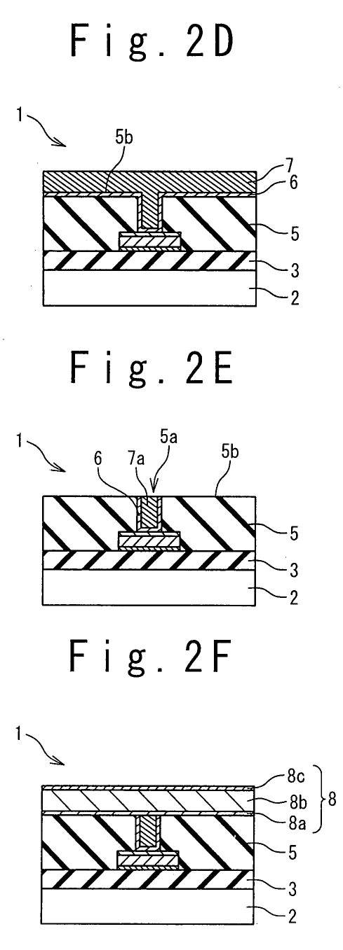

Next, a method of manufacturing the semiconductor device according to the semiconductor device of the present invention will be described in detail with reference to FIGS. 3 to 12.

FIG. 3 is a schematic diagram of a reactive sputtering apparatus 20 used for a process (the step S5) of forming the barrier layer 6. The reactive sputtering apparatus 20 has a reaction chamber 21 provided with a gas inlet 21a and a gas outlet 21b, DC power supplies 26 and 27; a high frequency power source 28; a susceptor 22 grounded through the high frequency power source 28; shields 23 grounded through the DC power supply 27; a target 24 grounded through the DC power supply 26; and a magnet 25 for generating a magnetic field in the reaction chamber 21. The reaction chamber 21 is grounded and can be freely vacuumed by a vacuum pump (not shown). The susceptor 22, the shields 23, and the target 24 are disposed in the reaction chamber 21. The target 24 is a titanium target. The susceptor 22 holds the semiconductor wafer 1 so that the semiconductor wafer 1 may face the target 24. The DC power supply 26 applies a negative DC potential to the target 24. That is, the DC power supply 26 lowers a potential of the target 24 below the ground potential. The DC power supply 27 applies the negative DC potential to the shields 23. That is, the DC power supply 27 lowers a potential of the shields 23 below the ground potential. The high frequency power source 28 applies an RF (Radio Frequency) bias as high frequency electric power to the semiconductor wafer 1 held by the susceptor 22. Moreover, a temperature of the substrate 2 is controlled by a temperature controller (not shown).

At the step S5, a mixed gas including an argon gas (Ar gas) and a nitrogen gas (N₂ gas) is supplied into the chamber 21 from the gas inlet 21a. Inert gas such as Kr or Xe may be used instead of the Ar gas. The RF bias is applied to the semiconductor wafer 1, while the mixed gas is introduced between the semiconductor wafer 1 and the target 24 so that the mixed gas may flow toward the central portion of the semiconductor wafer 1 from the peripheral portion of the semiconductor wafer 1. Then, plasma is generated in the reaction chamber 21 and a titanium nitride film is formed on the semiconductor wafer 1. The plasma is confined in a predetermined region with a magnetic field generated the magnet 25. The film qualities of the titanium nitride film such as a composition and a crystalline orientation (orientation) depend on a film formation condition. A part of nitrogen gas in the introduced mixed gas is absorbed by the titanium target 24. The mixed gas that concentration of nitrogen gas is reduced (a ratio of Ar gas is increased) diffuses between the semiconductor wafer 1 and the target 24 in a direction directed toward a central portion of the semiconductor wafer 1 from the peripheral portion thereof, and is discharged from the gas outlet 21b. Therefore, between the semiconductor wafer 1 and the target 24, a concentric distribution of nitrogen gaseous partial pressure is generated which is high in a region corresponding to the peripheral portion of the semiconductor wafer 1 and low in a region corresponding to the central portion thereof. This distribution of nitrogen gas becomes more remarkable as a total flow rate of the mixed gas introduced from the gas inlet 21a becomes smaller and as a diameter D of the semiconductor wafer 1 becomes larger. When the diameter D of the semiconductor wafer 1 is equal to or more than 12 inches (300 mm), an inclination of the nitrogen distribution becomes remarkable especially.

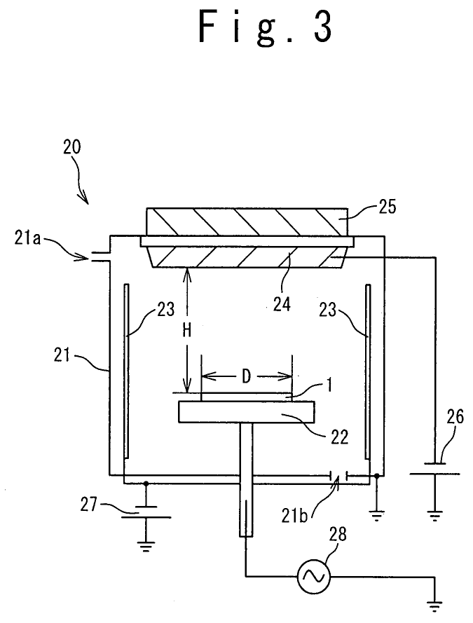

FIG. 4 shows first and third conditions as film formation conditions of a titanium nitride film in the method of manufacturing the semiconductor device according to the first embodiment of the present invention. A second condition is a film formation condition for comparison with the first condition. Parameters of the film formation condition to be set include: the thickness of the titanium nitride film to be formed (film thickness); a time required for film formation (time); the power of an RF bias applied by the high frequency source 28 (power); a ratio of a flow rate of the nitrogen gas to the total flow rate of the mixed gas (N₂ flow rate ratio); a flow rate of argon gas in the mixed gas (Ar flow rate); a flow rate of nitrogen gas in the mixed gas (N₂ flow rate); a spacing (H) between the semiconductor wafer 1 and the target 24; and a diameter D of the semiconductor wafer 1 (D).

First, a case where the titanium nitride film is formed as the barrier layer 6 under the second condition will be described. In the second condition, the film thickness is 50 nm, the time is 39 sec, the power 12 kw, the N₂ flow rate ratio 80.0%, the Ar flow rate is 24 sccm, the N₂ flow rate is 96 sccm, the spacing H 86 mm, and the diameter D 300 mm.

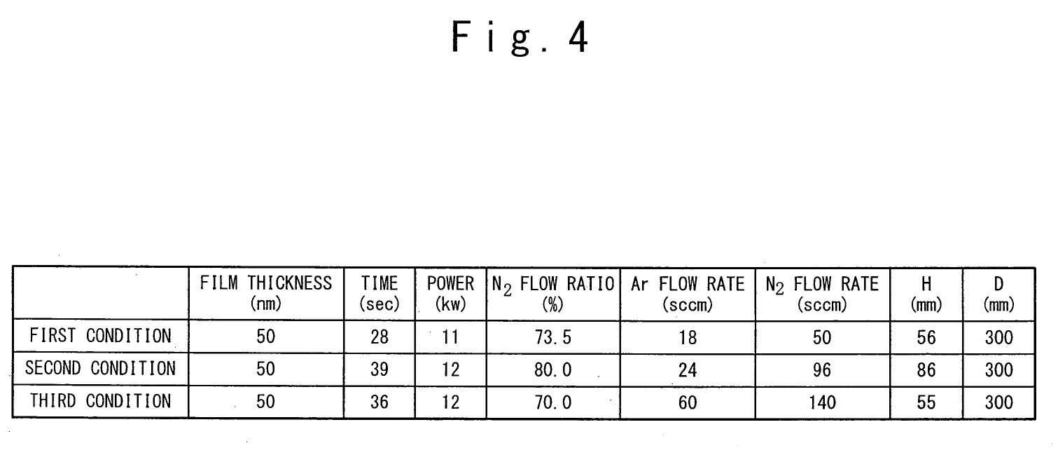

FIG. 5A is a graph showing an X-ray diffraction spectrum measured from the nitride titanium film formed in the central portion of the semiconductor wafer 1 under the second condition. FIG. 5B is a graph showing an X-ray diffraction spectrum measured from the nitride titanium film formed in the peripheral of the semiconductor wafer 1 under the second condition. Here, the titanium nitride film was formed by a reactive DC magnetron sputtering method using a titanium target. In FIGS. 5A and 5B, a vertical axis represents an X-ray diffraction intensity, and a horizontal axis represents an X-ray diffraction angle 2•. As shown in FIG. 5A, in the central portion of the semiconductor wafer 1, a peak indicating an orientation of TiN (111) was observed at about 36.5°, and a peak indicating an orientation of TiN (200) was observed at about 42.5°. In the central portion of the semiconductor wafer 1, the X-ray diffraction intensity at the peak indicating the orientation of TiN (111) was 38 count/s and the X-ray diffraction intensity at the peak that indicates the orientation of TiN (200) was 82 count/s. As shown in FIG. 5B, in the peripheral portion of the semiconductor wafer 1, the peak indicating the orientation of TiN (111) was not detected, whereas the peak indicating the orientation of TiN (200) was observed at about 42.5°. In the peripheral portion of the semiconductor wafer 1, the X-ray diffraction intensity at the peak indicating the orientation of TiN (200) was 140 count/s. That is, in the central portion of the semiconductor wafer 1, the titanium nitride film formed under the second condition had the orientation of TiN (111) and the orientation of TiN (200), whereas in the peripheral portion of the semiconductor wafer 1, it did not have the orientation of TiN (111) but had the orientation of TiN (200) more strongly.

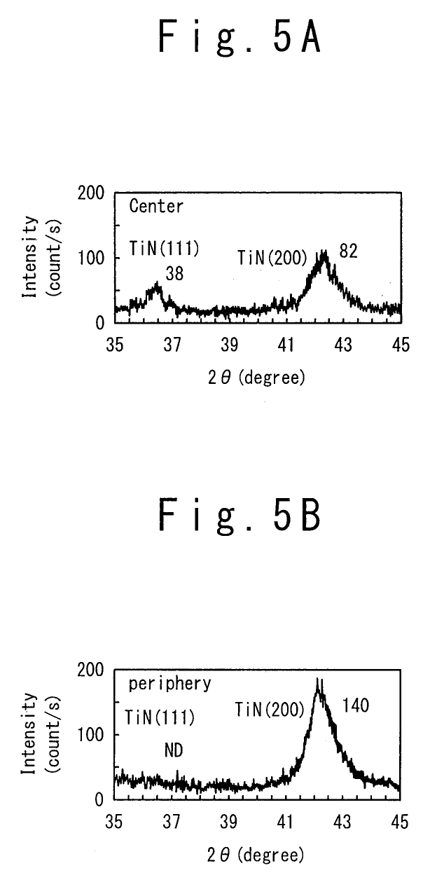

FIG. 6A is a graph showing an X-ray diffraction spectrum measured from the tungsten film 7 formed on the titanium nitride film in the central portion of the semiconductor wafer 1 under the second condition. FIG. 6B is a graph showing an x-ray diffraction spectrum measured from the tungsten film 7 formed on the titanium nitride film in the peripheral portion of the semiconductor wafer 1 under the second condition. Here, the tungsten film 7 was formed by the CVD method. In FIGS. 6A and 6B, the vertical axis represents the X-ray diffraction intensity, and the horizontal axis represents the X-ray diffraction angle 2•. As shown in FIGS. 6A and 6B, in the tungsten film 7, a peak indicating an orientation of W (110) was observed at about 40° and a peak indicating an orientation of W (200) was observed at about 58.5°. As shown in FIG. 6A, in the central portion of the semiconductor wafer 1, the X-ray diffraction intensity at the peak indicating the orientation of W (110) was 3169 count/s, whereas the X-ray diffraction intensity at the peak indicating the orientation of W (200) was as slight as 592 count/s. As shown in FIG. 6B, in the peripheral portion of the semiconductor wafer 1, the X-ray diffraction intensity at the peak indicating the orientation of W (110) was 1518 count/s, whereas the X-ray diffraction intensity at the peak indicating the orientation of W (200) was 4461 count/s. That is, in the central portion of the semiconductor wafer 1, the orientation of W (200) was main orientation, whereas in the peripheral portion of the semiconductor wafer 1, the orientation of W (110) was weak and the orientation of W (200) was strong.

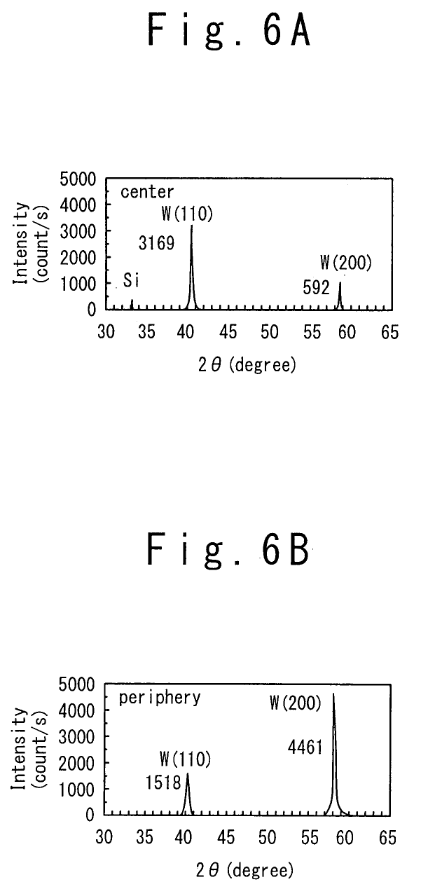

FIG. 7 is a top view of the semiconductor wafer 1 when the titanium nitride film was formed under the second condition, the tungsten film 7 was formed on it, and the tungsten film 7 was subjected to the CMP method. Here, the CMP method was finished when the tungsten film 7 in the central portion of the semiconductor wafer 1 is just polished. It took 50 seconds to perform the CMP method. In spite of having performed the same CMP process on the whole of the semiconductor wafer 1, a film residue of the tungsten film 7 is caused in the peripheral portion of the wafer. This is because a polishing rate of the tungsten film 7 under the same CMP process condition differs between the portion having the orientation of W (110) and the portion having the orientation of W (200). The polishing rate of the tungsten film 7 under this process condition was 200 mm/min in the portion having the orientation of W (200). Also, the polishing rate of the tungsten film 7 under this process condition in the portion having the orientation of W (110) was about 2.5 times larger than that the portion having the orientation of W (200). Therefore, it is important to make portions of the tungsten film 7 have the same orientation in the wafer in order to attain a uniform polishing rate. That is, it is important to make an orientation of the tungsten film 7 uniform over a wafer surface of the semiconductor wafer 1.

It should be noted that elongation of a CMP process time for removing the tungsten film 7 existing in the peripheral portion of the semiconductor wafer 1 is not desirable from the following reasons. That is, if the CMP process time is set longer, the insulating layer 5 becomes thin by being polished in the central portion of the semiconductor wafer 1, and accordingly a recess (dishing) in the neighborhood of the via-hole 5a becomes larger. As a result, a parasitic capacitance between the lower wiring layer 4 and the upper wiring layer 8 increases, and an RC time constant (Resistive-Capacitive time constant) of an electrical circuit including the lower wiring layer 4 and the upper wiring layer 8 increases. This delays signal propagation. Moreover, since a non-flat portion is formed in the processed wafer surface of the semiconductor wafer 1 through dishing, there arise problems such as resolution error in a lithography process and a process error in a subsequent process.

Next, a case where a titanium nitride film as the barrier layer 6 was formed under the first condition will be described. In the first condition, a film thickness is 50 nm, a time is 28 sec, a power is 11 kW, a N₂ flow rate ratio is 73.5%, an Ar flow rate is 18 sccm, a N₂ flow rate is 50 sccm, a spacing H is 56 mm, and a diameter D is 300 mm. A N₂ flow rate ratio in the first condition is smaller than that of the second conditions. In film formation under the first condition, a titanium nitride was formed that was titanium-rich compared with stoichiometric concentration.

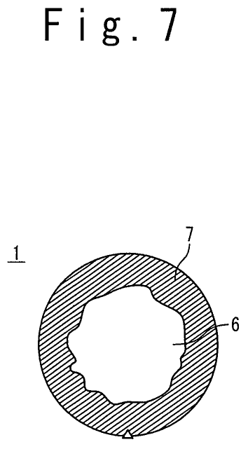

FIG. 8A is a graph showing an X-ray diffraction spectrum measured from the titanium nitride film under the first condition, in the central portion of the semiconductor wafer 1. FIG. 8B is a graph showing an X-ray diffraction spectrum measured from the titanium nitride film formed under the first condition, in the peripheral portion of the semiconductor wafer 1. Here, the titanium nitride film was formed by a reactive DC magnetron sputtering method using a titanium target. In FIGS. 8A and 8B, the vertical axis represents the X-ray diffraction intensity, and the horizontal axis represents the X-ray diffraction angle 2•. As shown in FIGS. 8A and 8B, a peak indicating the orientation of TiN (111) was observed at about 36.5° and a peak indicating the orientation of TiN (200) was observed at about 42.5°. As shown in FIG. 8A, in the central portion of the semiconductor wafer 1, an X-ray diffraction intensity at the peak indicating the orientation of TiN (111) is 93 count/s, and an X-ray diffraction intensity at the peak indicating the orientation of TiN (200) is 25 count/s. As shown in FIG. 8B, in the peripheral portion of the semiconductor wafer 1, the X-ray diffraction intensity at the peak indicating the orientation of TiN (111) was 49 count/s, and the X-ray diffraction intensity at the peak indicating the orientation of TiN (200) is 69 count/s. That is, the titanium nitride film formed under the first condition has the orientation of TiN (111) in both the central portion of and the peripheral portion of the semiconductor wafer 1.

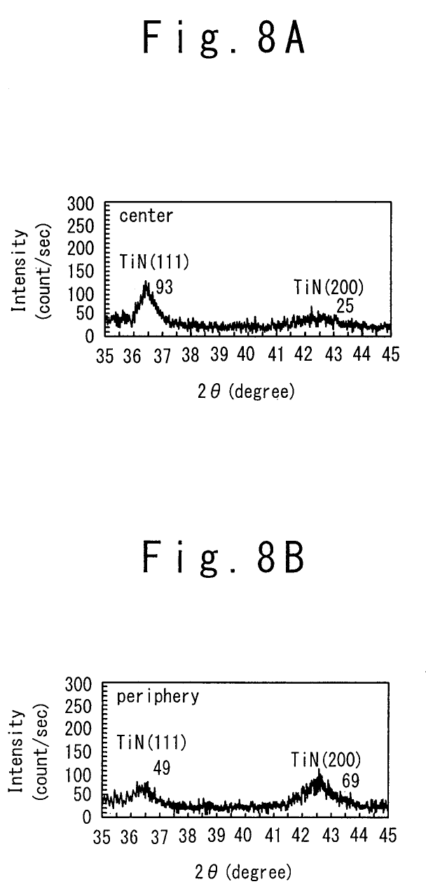

FIG. 9A shows a graph showing an X-ray diffraction spectrum measured from the tungsten film 7, which is formed on the titanium nitride film in the central portion of the semiconductor wafer 1 under the first condition shown in FIG. 4. FIG. 9B shows a graph showing an X-ray diffraction spectrum measured from the tungsten film 7 formed on the titanium nitride film in the peripheral portion of the semiconductor wafer 1 under the first condition. Here, the tungsten film 7 was formed by the CVD method. In FIGS. 9A and 9B, a vertical axis represents the X-ray diffraction intensity and a horizontal axis represents the X-ray diffraction angle 2•. As shown in FIGS. 9A and 9B, in the tungsten film 7, the large peak indicating the orientation of W (110) was observed at about 40°, and the small peak indicating the orientation of W (200) was observed at about 58.5°. As shown in FIG. 9A, in the central portion of the semiconductor wafer 1, the X-ray diffraction intensity at the peak indicating the orientation of W (110) is 6409 count/s, and the X-ray diffraction intensity at the peak indicating the orientation of W (200) is 321 count/s. As shown in FIG. 9B, in the peripheral portion of the semiconductor wafer 1, an X-ray diffraction intensity at the peak indicating the orientation of W (110) was 3123 count/s, and an X-ray diffraction intensity at the peak indicating the orientation of W (200) was 409 count/s. That is, in both the central portion of and the peripheral portion of the semiconductor wafer 1, the orientation of W (110) was main orientation.

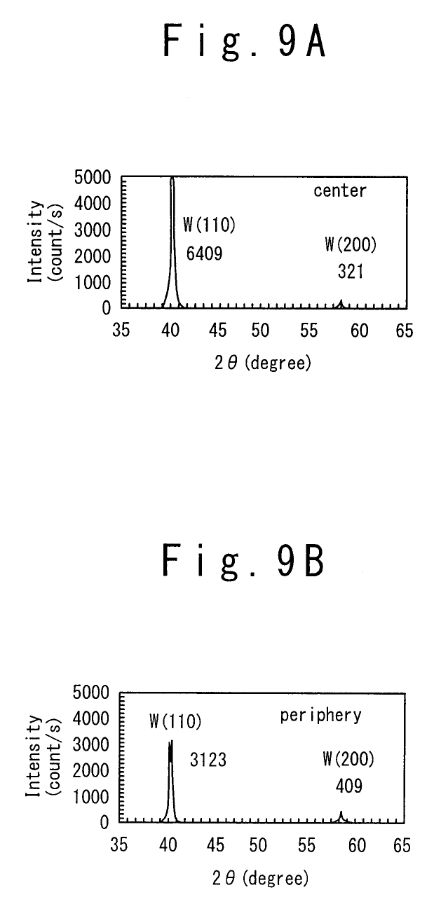

FIG. 10 is a top view of the semiconductor wafer 1 in case of forming a titanium nitride film under the first condition, forming the tungsten film 7 on it, and performing the CMP method on the tungsten film 7. Here, the CMP method was finished when the tungsten film 7 in the central portion of the semiconductor wafer 1 is polished away neither more nor less. As shown in FIG. 10, a film residue of the tungsten film 7 is not generated, and the insulating film 5 or the barrier layer 6 exposes over the whole surface of the semiconductor wafer 1. This is a desirable surface where polishing has been made. Suitable W-CMP can be made by setting over-polishing of about 15%.

Next, a third condition for forming a titanium nitride film as the barrier layer 6 will be described. In the third condition, a film thickness is 50 nm, a time is 36 sec, a power is 12 kW, an N₂ flow rate ratio is 70.0%, an Ar flow rate is 60 sccm, an N₂ flow rate is 140 sccm, a spacing H is 55 mm, and a diameter D is 300 mm. A total flow rate of the mixed gas (a flow rate that is a sum of the Ar flow rate and the N₂ flow rate) under the third condition is larger than the total flow rate of the mixed gas under the first condition. When the total flow rate of the mixed gas is large, a distribution of the nitrogen gas partial pressure produced between the semiconductor wafer 1 and the target 24 is loosened, and therefore the titanium nitride film formed under the third condition has more uniform orientation than the titanium nitride film formed under the first condition in FIG. 4.

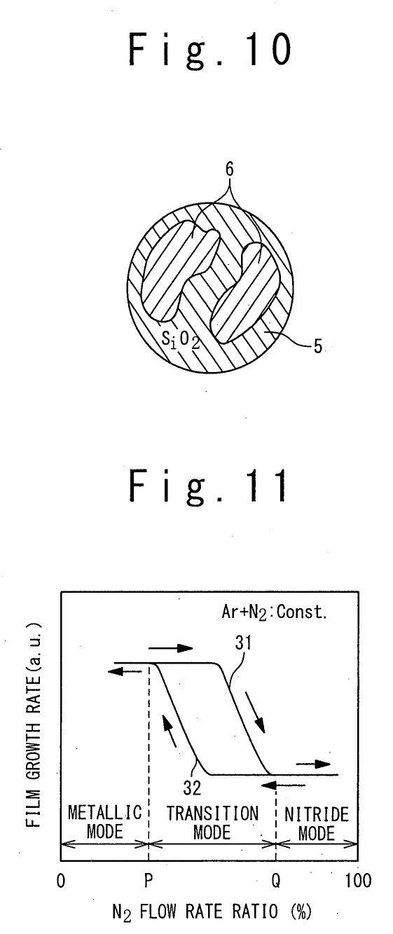

Generally, the film forming condition of the titanium nitride film at the step S5 can be set as follows. A method of setting the film forming condition of the titanium nitride film in the step S5 will be described with reference to FIG. 11. In FIG. 11, the vertical axis represents the film forming rate of titanium nitride film, and the horizontal axis represents the N₂ flow rate ratio. In forming a titanium nitride film using the reactive sputtering apparatus 20, if a film forming rate of the titanium nitride film is measured by varying an N₂ flow rate ratio while both the total flow rate of the mixed gas and the RF bias are maintained constant, curves 31 and 32 will be observed. The curve 31 shows a variation of the film forming rate when the N₂ flow rate ratio is increasing. The curve 32 shows a variation of the film forming rate when the N₂ flow rate ratio is decreasing. In a range where the N₂ flow rate ratio is larger than 0% and smaller than P %, the curve 31 and the curve 32 are coincident with each other. A range where the N₂ flow rate ratio is larger than 0% and smaller than P % is called a range of metallic mode. In a range where the N₂ flow rate ratio is equal to or larger than P % and also equal to or smaller than Q %, the curve 31 and the curve 32 are not coincident with each other, constituting a hysteresis loop. Here, P and Q are such that 0<P<Q<100. A range where the N₂ flow rate ratio is equal to or larger than P % and also equal to or smaller than Q % is called a range of transition mode. In a range where the N₂ flow rate ratio is larger than Q % and smaller than 100%, the curve 31 and the curve 32 are coincident with each other. The range where the N₂ flow rate ratio is larger than Q % and smaller than 100% is called the range of nitride mode.

Now, with increasing the N₂ flow rate ratio, a surface of the target 24 is much nitrided to form much titanium nitride (TiN). When the surface of the target 24 is nitrided, a sputtering rate S of the target 24 is decreased and the film-forming rate of the titanium nitride film deposited on the semiconductor wafer 1 is lowered. Here, the sputtering rate S is defined by S=Ns/Ni where Ni denotes the number of particles (ions) incident on the target 24 and Ns denotes the number of atoms (or molecules) of the target 24 that are sputtered by the particles. Therefore, in the range of transition mode, a hysteresis phenomenon that the curve 31 and the curve 32 are not coincident with each other due to an effect of the surface state of the target 24. If the titanium nitride film is formed on the semiconductor wafer 1 under a film formation condition that are within the range of transition mode, a film quality of the titanium nitride film is hard to make uniform over the whole wafer surface because nitriding is strong in the peripheral portion of the target 24 and weak in the central portion thereof. More specifically, the orientation of the titanium nitride film tends to differ between the central portion and the peripheral portion of the semiconductor wafer 1. When the diameter of the semiconductor wafer 1 is large, a difference of the film quality of the titanium nitride film tends to become prominent between the central portion and the peripheral portion of the semiconductor wafer 1.

When the titanium nitride film is formed on the semiconductor wafer 1 under a film formation condition within the range of nitride mode, the titanium nitride film has a composition close to stoichiometric concentration. On the other hand, when the titanium nitride film is formed on the semiconductor wafer 1 under the film formation condition within the range of metallic mode, the titanium nitride film has a titanium-rich composition. When the insulating film 6 as a base for the titanium nitride is an amorphous silicon oxide film (SiO₂ film), if the film is formed under film forming condition within the range of nitride mode, the orientation of TiN (200) becomes easily the main orientation over the whole wafer surface, whereas the film is formed under the film formation condition within the range of metallic mode, a composition tends to become titanium-rich and the main orientation tends to become the orientation of TiN (111) over the whole wafer surface. Therefore, what is necessary is just to obtain the data shown in FIG. 11 through a preliminary experiment and form the titanium nitride film under film forming condition within a range defined by subtracting the range of transition mode from the range where the N2 flow rate ratio is larger than 0% and less than 100% (the range of metallic mode and the range of nitride mode). In order to form the titanium nitride film whose orientation is uniform over the whole wafer surface, it is preferable to control the total flow rate of the introduced mixed gas, a sputtering pressure (a pressure in the reactive chamber 1), and a substrate temperature (the temperature of the substrate 2) so that the whole of the target 24 may be kept in a uniform nitride state. Thus, if the titanium nitride film is formed so that main orientation may become uniform over the whole wafer surface and the tungsten film 7 is formed by the CVD method on it, the polishing rate of the tungsten film 7 by the CMP method will become uniform over the whole wafer surface. Therefore, the film residue of the tungsten film 7 is prevented.

It is also possible to prevent the film residue of the tungsten film 7 by forming the titanium nitride film as the barrier layer 6 so that no main orientation may be substantially observed over the whole wafer surface. The fact that the no main orientation is substantially observed means that the main orientation is not observed, or that only a very weak main orientation is observed. When the characteristic of the barrier film is uniform, even if a main X-ray peak is small like this, the orientation of the film of CVD-W becomes substantially uniform, too. As a result, a uniform rate of the W-CMP can be achieved.

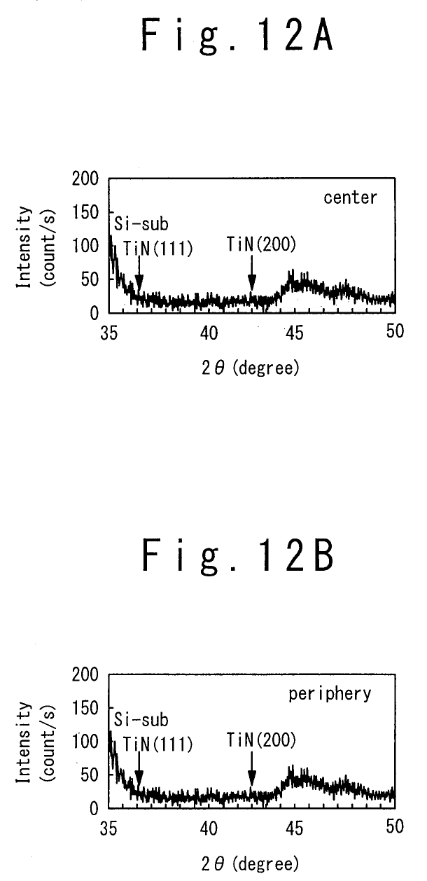

As a method of forming the titanium nitride film as the barrier layer 6 so that no main orientation may be substantially observed over the whole wafer surface, a case of using a high-ionization sputtering method will be described. The high-ionization sputtering method is a reactive sputtering method using plasma. In the high-ionization sputtering method, a film formation is performed under the condition that a pressure in the reaction chamber is controlled to be low and an ionization rate is high. In the high-ionization sputtering method, the reactive sputtering apparatus 20 is used to form the titanium nitride film on the semiconductor wafer 1 with an increased ionization ratio in such a way that a pressure in the reactive chamber 21 is controlled to be higher than 0.5 mTorr and lower than 2 mTorr, a substrate temperature of the semiconductor wafer 1 is controlled to be higher than a room temperature and lower than 50° C., a strong magnetic field is formed near the surface of the target 24 by the magnet 25, and a frequency of the RF bias is controlled to be higher than 40 MHz and lower than 200 MHz. Although it is also possible to increase the frequency higher than 200 MHz, it becomes important to control matching of impedance in order to suppress a reflected wave. FIGS. 12A and 12B show graphs of X-ray diffraction spectra of the titanium nitride film formed by a high-ionization sputtering method that is controlled such that a pressure in the reaction chamber 21 becomes a pressure slightly lower than 2 mTorr and a substrate temperature of the semiconductor wafer 1 becomes the room temperature approximately. FIG. 12A shows the X-ray diffraction spectrum measured in the central portion of the semiconductor wafer 1, and FIG. 12B shows the X-ray diffraction spectrum measured in the peripheral portion of the semiconductor wafer 1. In FIGS. 12A and 12B, a vertical axis represents the X-ray diffraction intensity and a horizontal axis represents the X-ray diffraction angle 2•. In these figures, arrows shows the X-ray diffraction angles 2• corresponding to the orientation of TiN (111) and the orientation of TiN (200), respectively. In both the central portion and the peripheral portion of the wafer, specific orientations could not be observed.

When the tungsten film 7 was formed by the CVD method on the titanium nitride film thus formed, the tungsten film 7 is formed to have a close-packed structure of a body-centered cubic lattice and to have a weak orientation of W (111) over the whole wafer surface. In addition, in this case, when the CMP method was performed on the tungsten film 7, the film residue of the tungsten film 7 is not produced as in case of forming the titanium nitride under the first condition.

The high-ionization sputtering method includes a self-ionization sputtering method. If it is possible to make suitable a coverage (cover rate) of the barrier layer 6 in the via-hole 5a, the following methods may be used: a usual magnetron sputtering method; a high-directivity sputtering method in which a spacing between a target and a substrate is increased and a film is formed at a low pressure; a sputtering method using a collimator; and a sputtering method in which directivity of flux is controlled by an electric field.

As so far described, a quality of the tungsten film 7 (orientation) becomes uniform over the whole wafer surface by forming the titanium nitride film as the barrier layer 6 so that its quality may become uniform over the whole wafer surface and forming thereon the tungsten film 7. This is because a crystal structure of the tungsten film 7 is affected by a surface state of a base material. Consequently, when the CMP method is performed on the tungsten film 7, the tungsten film 7 is removed in the same polishing rate from the central portion and the peripheral portion of the semiconductor wafer 1. The problems of the film residue of the tungsten film 7 due to insufficient polishing and of dishing in the neighborhood of the via-hole 5a due to an excessive polishing are solved. Therefore, a chip yield is improved.

The titanium nitride film can also be formed by the CVD method. In the CVD method, it is necessary to pay attention in treatment of residual impurities resulting from a raw material gas. Since the use of a raw material gas including an organic substance of titanium leaves carbon as a residual impurity, a subsequent plasma treatment and thermal treatment are required. Since the use of a raw material gas including titanium chloride leaves chlorine in the titanium nitride, a subsequent plasma treatment in an atmosphere including hydrogen gas is required. By performing these treatments appropriately, the CVD method is applicable as a method of forming the barrier layer 6.

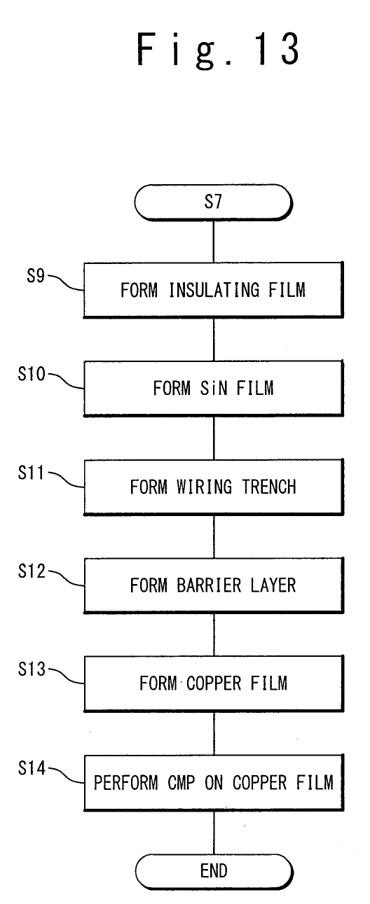

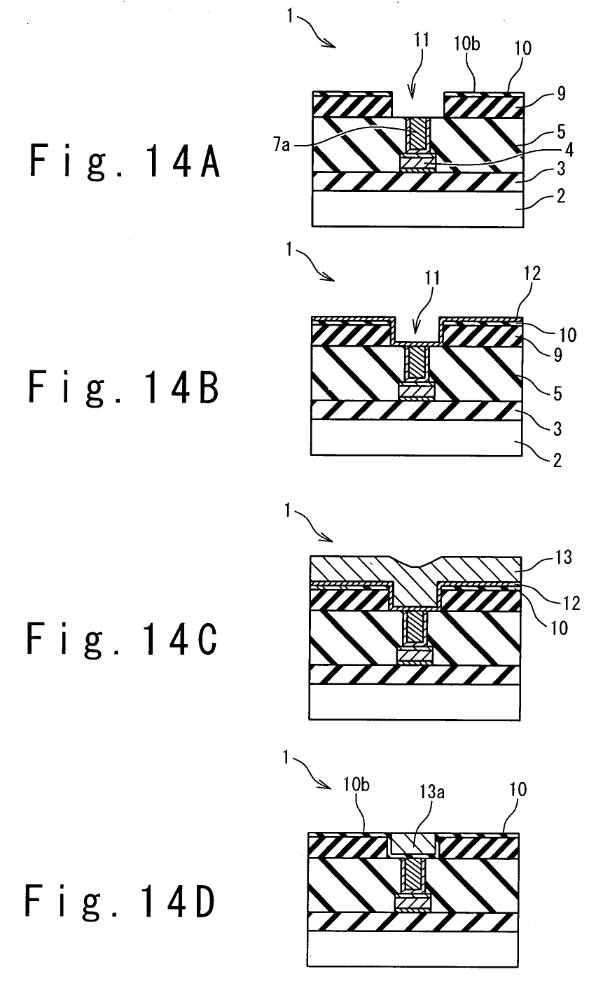

Next, a modification example of the method of manufacturing the semiconductor device according to the second embodiment of the present invention will be described with reference to FIGS. 13 and 14.

FIG. 13 is a flowchart showing a modification example of the method of manufacturing the semiconductor device according to the second embodiment of the present invention. Steps S9 to S14 shown in FIG. 13 are performed instead of the step S8 shown in FIG. 1. The steps S9 to S14 are a process of forming an upper wiring layer 13a instead of the upper wiring layer 8. The upper wiring layer 13a is a copper interconnection formed by a damascene method.

FIGS. 14A to 14D are sectional views of the semiconductor wafer to show a process of forming the upper wiring layer 13a in the method of manufacturing the semiconductor device according to the second embodiment of the present invention.

At the step S9, an insulating layer 9 is formed on the semiconductor wafer 1 shown in FIG. 2E. The insulating film 9 is formed as a silicon oxide film on the insulating film 5 to cover the tungsten plug 7a. Subsequently, at the step S10, a silicon nitride film (SiN film) 10 is formed on the insulating layer 9.

Next, at the step S11, an interconnection trench 11 is formed as a cavity (recess) of the insulating layer 9 and the SiN film 10, as shown in FIG. 14A. The tungsten plug 7a is exposed at the bottom of the interconnection trench 11. A part of the SiN film 10 on which the interconnection trench 11 is not formed is a flat section 10b.

Next, as shown in FIG. 14B, at the step S12, a barrier layer 12 is formed on the SIN film 10. The barrier layer 12 is a tantalum nitride film (TaN film) formed by a reactive sputtering method. The barrier layer 12 is formed by the same method as the above-mentioned method of forming the titanium nitride so that its orientation may become uniform over the whole wafer surface. In this case, the target 24 of tantalum (Ta) is used.

Next, as shown in FIG. 14C, at the step S13, a copper film 13 is formed on the barrier layer 12. The copper film 13 is formed by a plating method or a sputtering method. A part of the copper film 13 fills the interconnection trench 11, and the other part thereof is formed on the flat section 10b. Since a crystal structure of the copper film 13 is affected by a state of the barrier layer 12 as a base, the copper film 13 is formed so that its orientation may become uniform over the whole wafer surface.

Next, at the step S14, the copper film 13 is polished by the CMP method, so that the other part thereof formed on the flat section 10b is removed. By this polishing, the upper wiring layer 13a is embedded in the interconnection trench 11, as shown in FIG. 14D. The upper wiring layer 13a is connected with the tungsten plug 7a. At this time, since the orientation of the copper film 13 is uniform over the whole wafer surface, the copper film 13 is removed with the same polishing rate in both the central portion of and the peripheral portion of the semiconductor wafer 1. Therefore, the problems of film residue of the copper film 13 due to insufficient polishing and of dishing in the neighborhood of the interconnection trench 11 due to the excessive polishing are solved. Therefore, the chip yield is improved.

The tungsten plug 7a and the upper wiring layer 13a may be formed by a dual-damascene method.

What is claimed is:

1. A method of manufacturing a semiconductor device, comprising:
forming an insulating film with a concave portion on a semiconductor wafer;
forming a barrier layer on said insulating film to cover a surface of said insulating film such that said barrier layer has a uniform crystal orientation over a whole wafer surface of said semiconductor wafer;
forming a metal film on said barrier layer such that a portion of said metal film fills said concave portion; and
performing a CMP (Chemical Mechanical Polishing) on said metal film to leave the filling portion of said metal film.

2. The method according to claim 1, wherein said barrier layer comprises a nitride film of refractory metal.

3. The method according to claim 2, wherein said forming a nitride film of refractory metal comprises:
forming said nitride film of refractory metal by a reactive sputtering method.

4. The method according to claim 2, wherein said forming a nitride film of refractory metal comprises:
forming said nitride film of refractory metal by a chemical vapor deposition method.

5. The method according to claim 1, wherein said forming a barrier layer further comprises:
forming a film of a refractory metal, and
a nitride film of said refractory metal is formed on said refractory metal film as said barrier layer.

6. The method according to claim 2, wherein said refractory metal is selected from the group consisting of titanium (Ti), tantalum (Ta), and molybdenum (Mo).

7. The method according to claim 1, wherein said metal is tungsten (W).

8. The method according to claim 2, wherein said forming a barrier film comprises:
providing said semiconductor wafer and a refractory metal target in a reaction chamber to oppose to each other; and
supplying a mixed gas containing an inert gas and a nitrogen gas between said semiconductor wafer and said target to flow from a peripheral portion of said semiconductor wafer to a central portion thereof.

9. The method according to claim 8, wherein a nitrogen gas flow rate ratio as a ratio of a flow rate of the nitrogen gas to said mixed gas flow rate falls within a predetermined range in which a hysteresis is not observed in a change of a film forming rate of said metal nitride film when said nitrogen gas flow rate ratio is changed.

10. The method according to claim 8, wherein said inert gas is an argon gas.

11. The method according to claim 2, wherein said forming a nitride film of refractory metal comprises:
forming said titanium nitride film by a sputtering method using self ionization plasma.

12. The method according to claim 11, wherein said forming said titanium nitride film by a sputtering method using self ionization plasma comprises:
arranging said semiconductor wafer and a titanium target in a reaction chamber;
controlling a temperature of said semiconductor wafer to be higher than a room temperature and lower than 50° C.;
introducing the mixed gas containing an argon gas and a nitrogen gas into said reaction chamber;
controlling a frequency of a high frequency electric power to be higher than 40 MHz and lower than 200 MHz; and
controlling a pressure of said reaction chamber to be higher than 0.5 mTorr and lower than 2 mTorr.

13. The method according to claim 1, wherein said concave portion is a via-hole in a multi-level interconnection.

14. The method according to claim 2, wherein said concave portion is a trench for a multi-level interconnection.

15. The method according to claim 14, wherein said metal film is a copper film.
